(19) United States
(12) Patent Application Publication
(10) Pub. No.: US 2012/0313094 A1
(43) Pub. Date: Dec. 13, 2012

(54) SEMICONDUCTOR DEVICE AND MANUFACTURING METHOD THEREOF

(75) Inventor: Osamu KATO, Kanagawa (JP)

(73) Assignee: RENESAS ELECTRONICS CORPORATION, Kanagawa (JP)

(21) Appl. No.: 13/471,875

(22) Filed: May 15, 2012

(30) Foreign Application Priority Data
Jun. 10, 2011 (JP) 2011-129994

(51) Int. Cl. H01L 23/58; H01L 21/66

(52) U.S. Cl. 257/48; 438/11; 257/E23.002; 257/E21.531

(57) ABSTRACT

A semiconductor device which uses a semiconductor substrate having a TEG pattern to reduce defects induced by dicing. The semiconductor device includes a semiconductor substrate which is to be or has been divided into individual semiconductor chips by dicing; an interlayer insulating layer formed over the semiconductor substrate; a seal ring provided in the interlayer insulating layer and formed along the periphery of the semiconductor chip; and a TEG wiring having one end coupled to the seal ring and the other end extending toward an end face of the periphery of the semiconductor chip.

### CROSS-REFERENCE TO RELATED APPLICATIONS

The disclosure of Japanese Patent Application No. 2011-129994 filed on Jun. 10, 2011 including the specification, drawings and abstract is incorporated herein by reference in its entirety.

### BACKGROUND

The present invention relates to a semiconductor device and manufacturing method thereof.

In recent years, semiconductor devices which have various TEG (Test Element Group) elements to evaluate the characteristics of semiconductor devices in semiconductor chips in a manufacturing process have been proposed.

Japanese Unexamined Patent Publication No. 2007-180112 describes the following electronic device. Provided over a semiconductor wafer are pads electrically coupled to a semiconductor chip, seal rings for protecting the semiconductor chip during dicing, and a circuit characteristic evaluation area of a scribe line. Each seal ring is partially thinned. The wiring in the circuit evaluation area is located in a space created by thinning the seal ring. Since part of the seal ring area is used for the wiring in the circuit evaluation area in this way, the scribe line width can be decreased.

Japanese Unexamined Patent Publication No. 2010-205889 describes the following semiconductor device. A plurality of electrode terminals are provided over a semiconductor substrate having a multilayer interconnection structure. Seal rings are provided in the periphery of the semiconductor substrate. Impurity-doped regions are provided over the semiconductor substrate to couple the electrode terminals to the seal rings electrically. According to this technique, an abnormality in the periphery of the semiconductor device can be detected by measuring the resistance, etc. between two electrode terminals among the electrode terminals.

### SUMMARY

Electrode pads may be disposed in a dicing region to measure TEG elements as mentioned above. The present inventors have found that in that case, a serious degree of chipping or cracking may occur due to adhesion of electrode pad metal to the dicing blade. In particular, if chipping or cracking should destroy the seal rings, moisture absorbed through a dicing end may get into the inside of the chip and result in deterioration over time such as change in the dielectric constant of a low-k interlayer insulating layer.

According to a first aspect of the present invention, there is provided a semiconductor device which includes: a semiconductor substrate which is to be or has been divided into individual semiconductor chips by dicing; an interlayer insulating layer formed over the semiconductor substrate; a seal ring provided in the interlayer insulating layer and formed along a periphery of the semiconductor chip; and a TEG wiring having one end coupled to the seal ring and the other end extending toward an end face of the periphery of the semiconductor chip.

According to a second aspect of the present invention, there is provided a semiconductor device which includes: a semiconductor substrate which is to be or has been divided into individual semiconductor chips by dicing; an interlayer insulating layer formed over the semiconductor substrate; a seal ring provided in the interlayer insulating layer and formed along a periphery of the semiconductor chip; a TEG element provided on the inside of the seal ring in a plan view; a TEG wiring having one end coupled to the TEG element and the other end extending toward an end face of the periphery of the semiconductor chip without contact with the seal ring and beyond the seal ring; and a TEG wiring for element coupling having one end coupled to the TEG element and the other end coupled to the seal ring.

According to a third aspect of the present invention, there is provided a method for manufacturing a semiconductor device which includes the steps of forming a multilayer interconnection structure including an interlayer insulating layer over a semiconductor substrate which is divided into a plurality of semiconductor chips, forming a seal ring in the interlayer insulating layer along a periphery of the semiconductor chip at the step of forming the multilayer interconnection structure, and forming a TEG wiring having one end coupled to the seal ring and the other end extending toward an end face of the periphery of the semiconductor chip.

According to the present invention, the seal ring formed along the periphery of each semiconductor chip is used as a common wiring for a TEG pattern. This means that the number of electrode pads required for the TEG pattern can be decreased. Consequently the amount of metal swarf in dicing is decreased and chipping and cracking are reduced. Thus the invention provides a semiconductor device which uses a semiconductor substrate having a TEG pattern to reduce defects induced by dicing.

According to the present invention, a semiconductor device reduces defects induced by dicing by using a semiconductor substrate having a TEG pattern.

### BRIEF DESCRIPTION OF THE DRAWINGS

FIG. 1 is a plan view showing the structure of a semiconductor wafer according to a first embodiment of the invention;

FIGS. 2A and 2B are plan views showing the structure of the semiconductor device according to the first embodiment;

FIG. 3 is an equivalent circuit diagram for a TEG pattern according to the first embodiment;

FIG. 4 is a sectional view showing the structure of the semiconductor device according to the first embodiment;

FIGS. 5A and 5B show a TEG element according to the first embodiment in enlarged form;

FIG. 6 is a flowchart showing a method for manufacturing the semiconductor device according to the first embodiment;

FIGS. 7A and 7B show a TEG element according to a second embodiment of the invention in enlarged form;

FIGS. 8A and 8B show a TEG element according to a third embodiment of the invention in enlarged form;

FIG. 9 is a plan view showing the structure of the semiconductor device according to a fourth embodiment of the invention;

FIG. 10 is an equivalent circuit diagram for a TEG pattern according to the fourth embodiment;

FIGS. 11A and 11B show a TEG element according to the fourth embodiment in enlarged form;

FIG. 12 is a plan view showing the structure of a semiconductor device according to a fifth embodiment of the invention;

FIG. 13 is an equivalent circuit diagram for a TEG pattern according to the fifth embodiment;

FIGS. 14A and 14B show a TEG element according to the fifth embodiment in enlarged form;

FIG. 15 is a plan view showing the structure of a semiconductor device according to a sixth embodiment of the invention;

FIG. 16 is an equivalent circuit diagram for a TEG pattern according to the sixth embodiment;

FIG. 17 is a plan view showing the structure of a semiconductor device according to a seventh embodiment of the invention;

FIG. 18 is a plan view showing the structure of a semiconductor device according to an eighth embodiment of the invention;

FIG. 19 is a sectional view showing the structure of the semiconductor device according to the eighth embodiment;

FIG. 20 is a sectional view showing the structure of a semiconductor device according to a ninth embodiment of the invention; and

FIGS. 21A and 21B are plan views showing the structure of a semiconductor device according to a tenth embodiment of the invention.

### DETAILED DESCRIPTION

Next, the preferred embodiments of the present invention will be described referring to the accompanying drawings. In all the drawings, elements with like functions are designated by like reference numerals and descriptions thereof are not repeated.

### First Embodiment

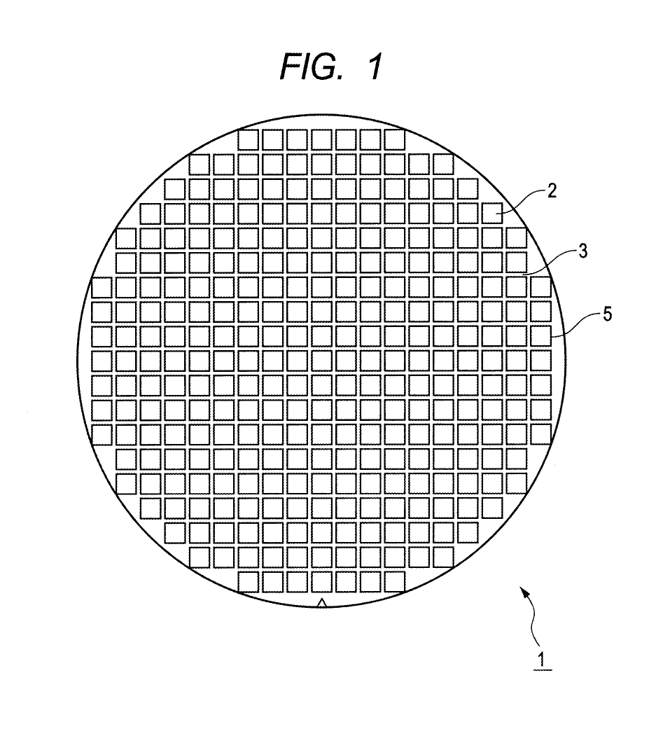

A semiconductor device 10 according to the first embodiment will be described below referring to FIGS. 1 to 5B. The semiconductor device 10 is structured as follows. The semiconductor device includes a semiconductor substrate 100 which is to be divided or has been divided into individual semiconductor chips 2 by dicing, an interlayer insulating layer 200 formed over the semiconductor substrate 100, a seal ring 5 provided in the interlayer insulating layer 200 and formed along the periphery of the semiconductor chip 2, and a TEG wiring 7 having one end coupled to the seal ring 5 and the other end extending toward an end face of the periphery of the semiconductor chip 2. A detailed explanation is given below.

In the semiconductor device 10 described below, the semiconductor substrate 100 may be not divided into the individual semiconductor chips 2 yet. In other words, the semiconductor device 10 may be not in the form of an individual chip but may be on the undivided (undiced) wafer to be supplied to an assembly manufacturer. Alternatively, the semiconductor device 10 may be the individual semiconductor chip 2 as a result of dicing the semiconductor substrate 100.

First, a semiconductor wafer 1 used in this embodiment will be described referring to FIG. 1. FIG. 1 is a plan view showing the structure of the semiconductor wafer 1 according to the first embodiment. As shown in FIG. 1, the semiconductor wafer 1 is divided into a plurality of regions as semiconductor chips 2 with a dicing region 3 between them. The semiconductor wafer 1 is, for example, a silicon wafer. The “semiconductor substrate 100” described below may be a substrate as an undivided “semiconductor wafer 1” or a substrate as an individual “semiconductor chip 2” from a divided wafer. The “dicing region 3” here means a region which includes not only a cutting region 4 in which cutting is done with a dicing blade but also a margin provided in consideration of the positioning accuracy of the dicing blade or chipping in dicing.

In the semiconductor chip 2, a semiconductor element (not shown) is formed and a multilayer interconnection structure is formed in the interlayer insulating layer 200 which will be described later.

Also the seal ring 5 lies along the periphery of the semiconductor chip 2. The seal ring 5 is a wiring trench in which metal is buried, penetrating the interlayer insulating layer 200. Therefore, if the interlayer insulating layer 200 is a low-k layer, the ring prevents moisture penetration.

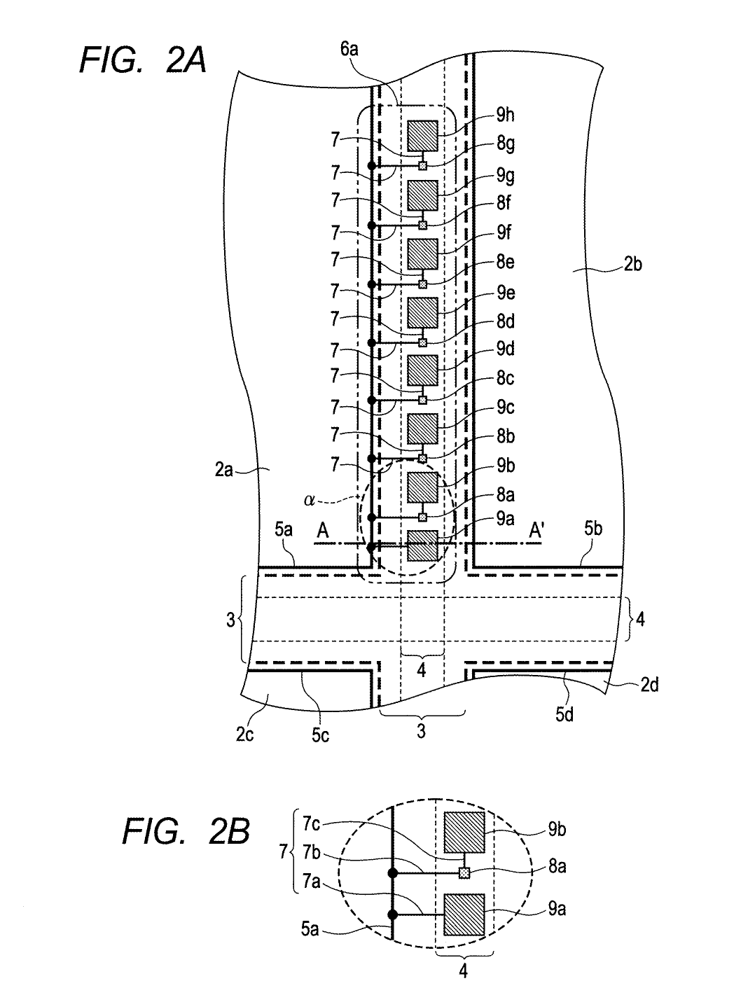

FIGS. 2A and 2B are plan views of the semiconductor device 10 according to the first embodiment, in which FIG. 2A shows part of the dicing region shown in FIG. 1 in enlarged form and FIG. 2B is an enlarged view of area α in FIG. 2A.

As shown in FIG. 2A, seal rings 5a, 5b, 5c, and 5d are provided along the peripheries of semiconductor chips 2a, 2b, 2c, and 2d respectively.

The region surrounded by the seal ring 5a and so on has a dicing region 3 for dividing the wafer into the semiconductor chip 2a and so on. In an actual dicing process, cutting is done with a dicing blade in a cutting region 4 which is in the center of the dicing region 3.

A TEG pattern 6a in the first embodiment is an area expressed by two-dot chain line in the figure. The TEG pattern 6a has TEG wirings 7 each having one end coupled to the seal ring 5a and the other end extending toward the end face of the periphery of the semiconductor chip 2. Therefore, the seal ring 5a can be used as a common wiring for the TEG pattern 6a.

In addition to the TEG wirings 7, the TEG pattern 6a has electrode pads 9a to 9h for applying voltage to the TEG pattern 6a. The electrode pad 9a and so on are located in the dicing region 3 outside the seal ring 5a and so on in a plan view.

The electrode pad 9a and so on, lying directly on the top layer of the interlayer insulating layer 200, are coupled to the TEG wirings 7a for electrode coupling as shown in FIG. 2B. The “TEG wiring 7a for electrode coupling” here means TEG wirings 7 which couple the seal ring 5a and so on to the electrode pad 9a and so on in the vicinity of the top layer of the interlayer insulating layer 200. The electrode pad 9a and so on can be used for measurement with a sensing pin in a testing process.

The width of the electrode pad 9a is smaller than that of the dicing blade used for dicing the semiconductor substrate 100. Preferably the electrode pad 9a and so on are located inside the cutting region 4 of the dicing region 3. In that case, the electrode pad 9a is all cut out by dicing. For this reason, when wire-bonding the semiconductor chips 2 after dicing, no short-circuiting occurs between wires.

Furthermore, the TEG pattern 6a includes TEG elements 8a to 8g. The “TEG elements” here refer to elements formed in accordance with the same design rules as the semiconductor elements (not shown) in the semiconductor chip 2. This means that they provide the same performance as the semiconductor elements in the semiconductor chip 2. Therefore, testing of the TEG element 8a and so on to check for a defect in performance is equivalent to testing of the semiconductor elements in the semiconductor chip 2 to check for a defect in performance.

The TEG element 8a and so on are formed in the semiconductor substrate 100 or the interlayer insulating layer 200 and coupled to the seal ring 5a and so on through the TEG wirings 7b for element coupling. The “TEG wiring(s) 7b for element coupling” here means TEG wirings 7 which couple the seal ring 5a and so on to the TEG elements 8a and so on in the interlayer insulating layer. In the first embodiment, the TEG element 8a and so on are located in the dicing region 3.

Also provided are third TEG wirings 7c to be coupled to the TEG element 8a and so on and vias (not shown) for coupling the third TEG wirings 7c to the electrode pad 9a and so on. The “third TEG wirings 7c” here refer to TEG wirings 7 which are coupled to the TEG wiring 8a and so on and coupled to the electrode pad 9a and so on through the vias (not shown) in the interlayer insulating layer 200. Hereinafter, the TEG wiring 7a for electrode coupling, TEG wiring 7b for element coupling and third TEG wiring 7c are collectively referred to as TEG wiring(s) 7 unless otherwise specified.

The seal ring 5a which is coupled to the TEG wiring 7 is, for example, a grounding wiring. In that case, no unfavorable influence is brought to the semiconductor elements in the semiconductor chip 2a in a testing process with the TEG pattern 6a.

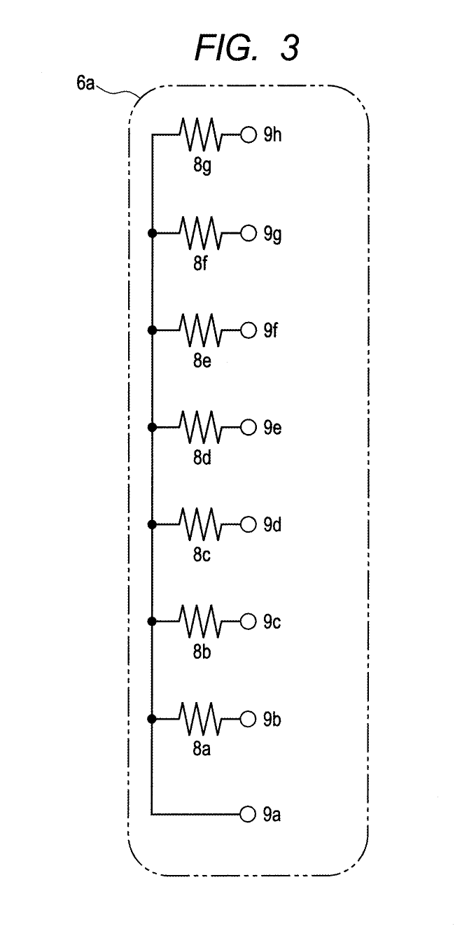

Next, FIG. 3 is an equivalent circuit diagram for the TEG pattern 6a according to the first embodiment. As shown in FIG. 3, the TEG element 8a and so on in the TEG pattern 6a in the first embodiment include resistances. This means that the resistances of a portion of the semiconductor chip 2 having the same pattern as the TEG element 8a and so on can be measured.

For example, the TEG elements 8a to 8g are coupled in parallel as shown in FIG. 3. As described above, the seal ring 5a is used as a common wiring for coupling the electrode pad 9a to the TEG element 8a and so on.

For example, the resistance of the TEG element 8a can be measured by applying voltage between the electrode pads 9a and 9b and measuring the current. Similarly, if an abnormal resistance is found as a result of measuring the TEG elements 8a to 8g, the semiconductor chip 2a or 2b in the vicinity of the TEG pattern 6a may be considered to include a defective element. The method for manufacturing the semiconductor device 10 including a testing process will be detailed later.

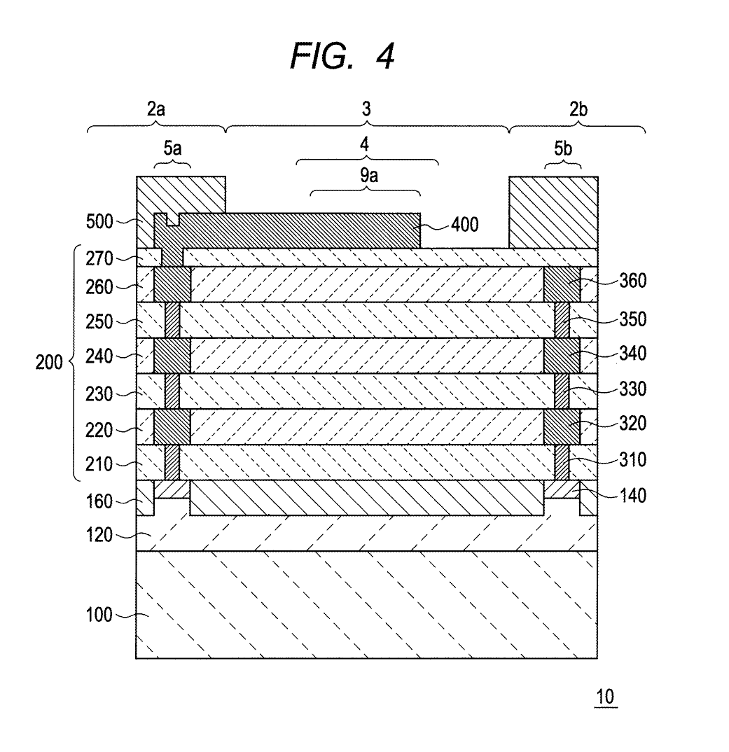

FIG. 4 is a sectional view showing the structure of the semiconductor device 10 according to the first embodiment. FIG. 4 is a sectional view taken along the line A-A′ of FIG. 2.

As shown in FIG. 4, a well 120 is formed over the semiconductor substrate 100. The well 120 is a P type well doped with boron.

An element isolation region 160 is formed over the semiconductor substrate 100. The element isolation region 160 has openings under the seal ring 5a and so on. The element isolation region 160 is, for example, SiO₂ film.

A diffusion layer 140 doped with impurities having the opposite conductivity to the well 120 of the semiconductor substrate 100 is provided in portions of the semiconductor substrate 100 which are in contact with the seal ring 5a and so on. Consequently, even when voltage is applied in the process of testing the TEG pattern 6a, no over-current will flow to the semiconductor chip 2.

For example, if the well 120 is a P type well, the diffusion layer 140 is an N type diffusion layer doped with As.

The interlayer insulating layer 200 is formed over the semiconductor substrate 100. The interlayer insulating layer 200 includes, for example, a first via formation insulating layer 210, a first wiring formation insulating layer 220, a second via formation insulating layer 230, a second wiring formation insulating layer 240, a third via formation insulating layer 250, a third wiring formation insulating layer 260, and a fourth interlayer insulating layer 270. In this embodiment, the number of sub-layers in the interlayer insulating layer 200 is not limited and may be larger or smaller than the above.

The interlayer insulating layer 200 includes, for example, a low-k layer with a dielectric constant of 3 or less. This decreases the capacitance between wirings, leading to reduction in the impedance of the semiconductor device 10 as a whole. The materials of the low-k layer may be SiO₂ and SiOC. The low-k layer may be porous.

Among the sub-layers of the interlayer insulating layer 200, the fourth interlayer insulating layer 270 adjacent to the electrode pad 9a is, for example, SiN film. By using a film with high mechanical strength like this, the inside of the semiconductor chip 2a and so on can be protected during testing with a sensing pin.

On the other hand, the first via formation insulating layer 210 is formed directly on the semiconductor substrate 100. In the first via formation insulating layer 210, first vias 310 are formed along the peripheries of the semiconductor chip 2a and so on.

The first wiring formation insulating layer 220 is formed over the first via formation insulating layer 210. In the first wiring formation insulating layer 220, first wirings 320 which are larger in width than the first vias 310 are formed along the peripheries of the semiconductor chip 2a and so on.

Similarly, in the second via formation insulating layer 230, second wiring formation insulating layer 240, third via formation insulating layer 250 and third wiring formation insulating layer 260, second vias 330, second wirings 340, third vias 350, and third wirings 360 are formed in order along the peripheries of the semiconductor chip 2a and so on.

The fourth interlayer insulating layer 270 is formed over the third wiring formation insulating layer 260. The fourth interlayer insulating layer 270 has an opening above the third wiring 360 in the seal ring 5a. A fourth via (not shown) may be formed just above the third wiring 360 in the fourth interlayer insulating layer 270.

Over the fourth interlayer insulating layer 270, a fourth wiring 400 including the electrode pad 9a is formed in a way to be coupled to the third wiring 360. The fourth wiring 400 includes the electrode pad 9a and TEG wiring 7 for electrode coupling. In the fourth wiring 400 shown in the figure, the portion from the point of coupling to the third wiring 360 to the electrode pad 9a is an area for the TEG wiring 7 for electrode coupling.

The fourth wiring 400 is made of, for example, Al. In other words, the electrode pad 9a and TEG wiring 7 for electrode coupling are made of, for example, Al. The electrode pad 9a and TEG wiring 7 for electrode coupling are located directly on the top layer (fourth interlayer insulating layer 270) of the interlayer insulating layer 200. Therefore, in the testing process, touching with a sensing pin is easy and the contact resistance is decreased.

A passivation film 500 is formed over the fourth interlayer insulating layer 270 and the fourth wiring 400. In the passivation film 500, an opening is made in the dicing region 3. Consequently the electrode pad 9a and the TEG wiring 7 for electrode coupling are partially exposed.

For example, Cu is used for the first wiring 320, second wiring 340 and third wiring 360. On the other hand, for example, W or Cu is used for the first vias 310, second vias 330, and third vias 350.

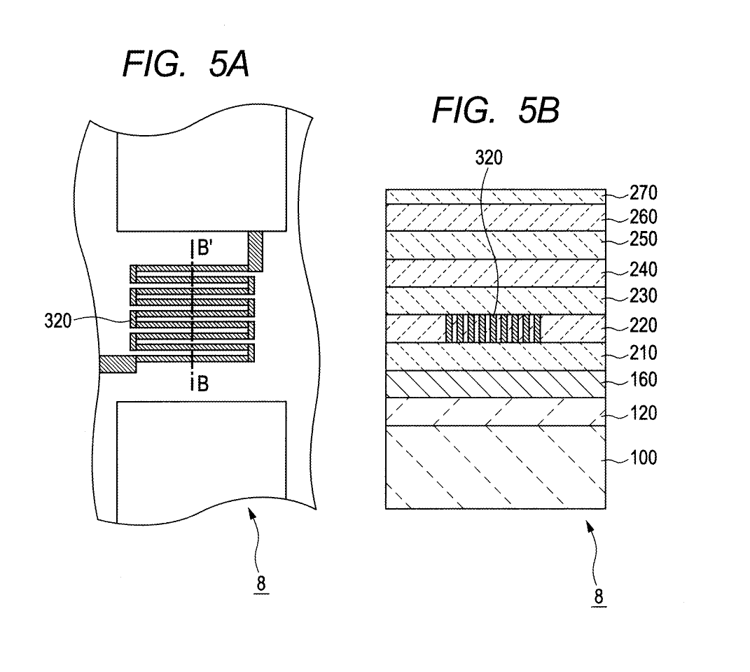

Next, the TEG elements 8 according to the first embodiment will be described referring to FIGS. 5A and 5B. FIGS. 5A and 5B show a TEG element 8 according to the first embodiment in enlarged form, in which FIG. 5A is a plan view and FIG. 5B is a sectional view taken along the line B-B′ of FIG. 5A. The TEG element 8a and so on are hereinafter collectively referred to as the “TEG element(s) 8” in the explanation of the first and other embodiments.

Referring to FIG. 5A, the TEG element 8 may be a resistance as mentioned earlier. The resistance is, for example, a wiring resistance. In the first embodiment, the wiring resistance is formed by folding the first wiring 320 several times in a plan view.

As shown in FIG. 5B, the TEG element 8 is provided as the first wiring 320 in the first wiring formation insulating layer 220. This means that the resistance of a specific wiring layer in the semiconductor chip 2 can be predicted. In this case, the resistance of the first wiring 320 can be predicted.

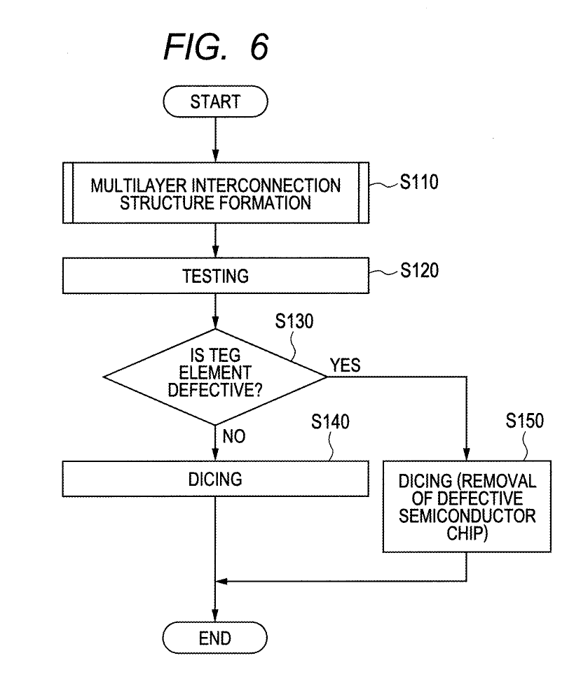

Next, the method for manufacturing the semiconductor device 10 according to the first embodiment will be described referring to FIG. 6. FIG. 6 is a flowchart showing the method for manufacturing the semiconductor device 10 according to the first embodiment. The method for manufacturing the semiconductor device 10 according to the first embodiment includes the step of forming a multilayer interconnection structure including the interlayer insulating layer 200 over a semiconductor substrate 100 which is divided into a plurality of individual semiconductor chips 2. At the step of forming the multilayer interconnection structure, the seal ring 5 is formed in the interlayer insulating layer 200 along the periphery of the semiconductor chip 2 and a TEG wiring 7 having one end coupled to the seal ring 5 and the other end extending toward the end face of the periphery of the semiconductor chip 2 is formed. The details of the method are explained below.

Referring to FIG. 6, a multilayer interconnection structure including the interlayer insulating layer 200 is formed over the semiconductor substrate 100 which will be diced into individual semiconductor chips 2 (multilayer interconnection structure formation step: S110). This step includes the following sub-steps. The order of the following sub-steps is not limited to the order given below but may be changed in the order of lamination or any other order.

At the step of forming the multilayer interconnection structure, a seal ring 5 is formed in the interlayer insulating layer 200 along the periphery of the semiconductor chip 2.

A TEG wiring 7a having one end coupled to the seal ring 5 and the other end extending toward the end face of the periphery of the semiconductor chip 2 is formed.

In the dicing region 3 outside the seal ring 5 in a plan view, an electrode pad 9a and so on which are coupled to the TEG wirings 7 for electrode coupling are formed directly on the top layer of the interlayer insulating layer 200.

TEG elements 8 which are coupled to the seal ring 5 through the TEG wirings 7b for element coupling are formed in the semiconductor substrate 100 or the interlayer insulating layer 200.

The above sub-steps are carried out in the step of forming the multilayer interconnection structure. The semiconductor device 10 having the TEG pattern 6a is thus formed.

Next, the TEG elements 8 are tested by applying voltage to the TEG pattern 6a through the electrode pad 9a and so on (testing step: S120).

Referring to FIG. 2B, in the first embodiment, voltage is applied to the electrode pads 9a and 9b to measure the current to obtain the resistance of the TEG element 8a. This means that the resistance of the first wiring 320 in the semiconductor chip 2a can be predicted.

Also, by applying voltage to the electrode pads 9a and 9c, 9a and 9d and so on to measure the currents similarly, the average of the resistances of the TEG elements 8a to 8g can be obtained.

The content of testing may vary with TEG elements 8. Also, different voltages may be applied between the electrode pads 9a and 9b and between the electrode pads 9b and 9c and so on.

If a defect is found in a TEG element 8 at the testing step (YES at S130), it is considered that a semiconductor element (not shown) in the semiconductor chip 2 (for example, the semiconductor chip 2a) adjacent to the TEG pattern 6a is defective. On the other hand, if no defect is found in the TEG elements 8 (NO at S130), it is considered that the semiconductor elements (not shown) in the semiconductor chip 2 (for example, the semiconductor chip 2a) adjacent to the TEG pattern 6a have no defect and are allowed to be shipped.

Next, after the testing step (S120), a dicing step is carried out in which dicing is done in the dicing region 3 of the semiconductor substrate 100 including the electrode pad 9a and so on to divide the substrate into a plurality of individual semiconductor chips 2. A dicing blade is used for dicing. The cutting region 4 is scribed with the dicing blade to divide the semiconductor substrate 100.

If at the testing step (S120) a defect is found in the TEG elements 8 (YES at S130), dicing is done and the semiconductor chip 2 which is judged as defective (for example, the semiconductor chip 2a) is removed (S150).

On the other hand, if at the testing step (S120) no defect is found in the TEG elements 8 (NO at S130), dicing is done and all semiconductor chips 2 are allowed to be shipped (S140).

Next, the advantageous effects of the first embodiment will be described.

Suppose a case as a comparative example that the seven TEG elements 8a to 8g shown in FIG. 3 each have two electrode pads (not shown). In this case, a total of 14 electrode pads are needed. If many electrode pads are disposed in the dicing region 3 as in this case, metal from the electrode pads is more likely to adhere to the dicing blade and chipping or cracking would be more conspicuous. Particularly if chipping or cracking which destroys the seal ring occurs, the moisture absorbed through a dicing end may reach the inside of the chip, resulting in deterioration over time such as change in the dielectric constant of the low-k interlayer insulating layer 200.

On the other hand, in the first embodiment, the seal ring 5 which lies along the periphery of the semiconductor chip 2 as shown in FIG. 1 is used as a common wiring for the TEG pattern 6a. This can decrease the number of electrode pads required for the TEG pattern 6a. As shown in FIG. 2A, the seven TEG elements 8a to 8b can be measured through the eight electrode pads 9a to 9h.

By decreasing the number of electrode pads in this way, the amount of metal swarf in dicing is decreased, thereby reducing chipping or cracking.

As discussed above, according to the first embodiment, the semiconductor device 10 reduces defects induced by dicing by the use of a semiconductor substrate having the TEG pattern 6a.

### Second Embodiment

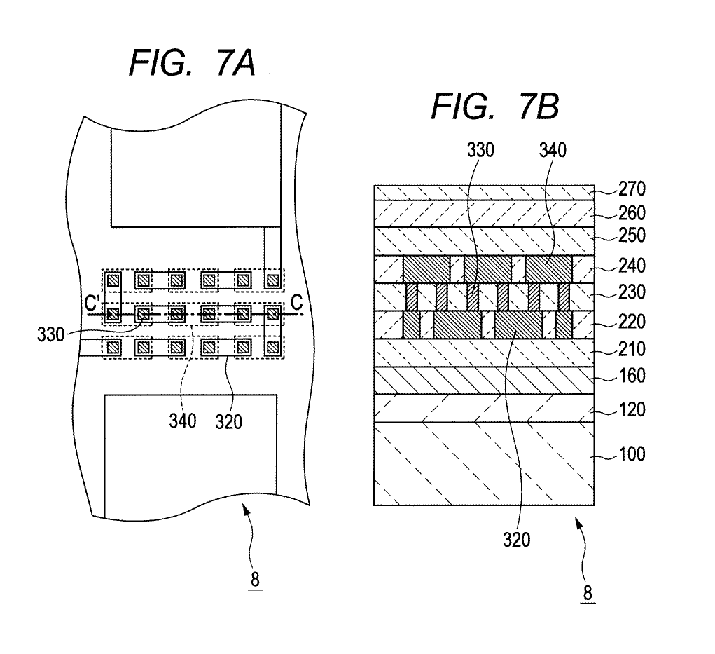

FIGS. 7A and 7B show a TEG element 8 according to the second embodiment in enlarged form. FIG. 7A is a plan view of the TEG element 8 according to the second embodiment and FIG. 7B is a sectional view taken along the line C-C′ of FIG. 7A. The second embodiment is the same as the first embodiment except the structure of the TEG element 8. A detailed explanation is given below.

Referring to FIG. 7A, the TEG element 8 in the second embodiment is a wiring resistance as in the first embodiment. However, in the second embodiment, the wiring resistance includes a plurality of vias (second vias 330) in the interlayer insulating layer 200. This means that the wiring resistance can be formed in a way to cover many sub-layers of the interlayer insulating layer 200. In addition, due to the presence of the vias (not shown), the TEG element 8 can be coupled to the electrode pads 9b to 9h. In this case, the TEG element 8 is comprised of the first wirings 320, second vias 330, and second wirings 340, forming an S-shaped wiring resistance in a plan view.

As shown in FIG. 7B, the TEG element 8 is formed so as to make a few folds from the first wirings 320 to the second wirings 340 through the second vias 330 in the cross-sectional direction. This means that the resistance of the second vias 330 can be predicted.

### Third Embodiment

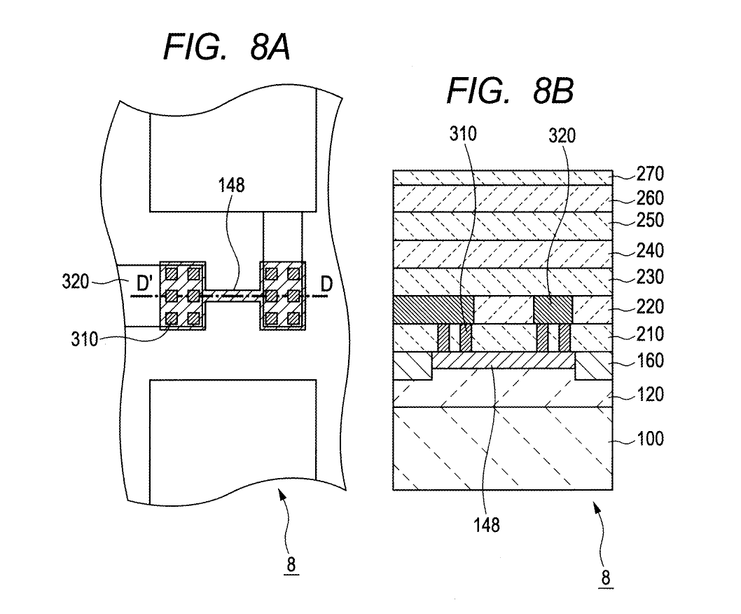

FIGS. 8A and 8B show a TEG element 8 according to the third embodiment in enlarged form. FIG. 8A is a plan view of the TEG element 8 according to the third embodiment and FIG. 8B is a sectional view taken along the line D-D′ of FIG. 8A. The third embodiment is the same as the first embodiment except the structure of the TEG element 8. A detailed explanation is given below.

Referring to FIG. 8A, the TEG element 8 in the third embodiment is a resistance as in the first embodiment. However, in the third embodiment, the resistance is a diffusion resistance layer 148 doped with impurities in the semiconductor substrate 100. The diffusion resistance layer 148 is doped with the same impurities in the same amount as the diffusion layer 140 of the semiconductor chip 2. This means that the resistance of the diffusion layer 140 of the semiconductor chip 2 can be predicted. The TEG element 8 here is comprised of first vias 310, first wirings 320 and the diffusion resistance layer 148. The diffusion resistance layer 148 is H-shaped in a plan view, in which the area between the first vias 310 is an area for measurement.

As shown in FIG. 8B, the diffusion resistance layer 148 lies in the opening of the element isolation region 160. The first vias 310 are located directly on the diffusion resistance layer 148 and coupled to the first wirings 320. In FIG. 8B, the left first wiring 320 extends toward the seal ring 5a and is coupled to the seal ring 5a. On the other hand, in FIG. 8B, the right first wiring 320 is coupled to vias (not shown) to be coupled to the electrode pad 9b and so on. The resistance of the diffusion resistance layer 148 can be obtained by applying voltage between electrode pads (not shown) coupled to the first wirings 320 at both ends and measuring the current.

### Fourth Embodiment

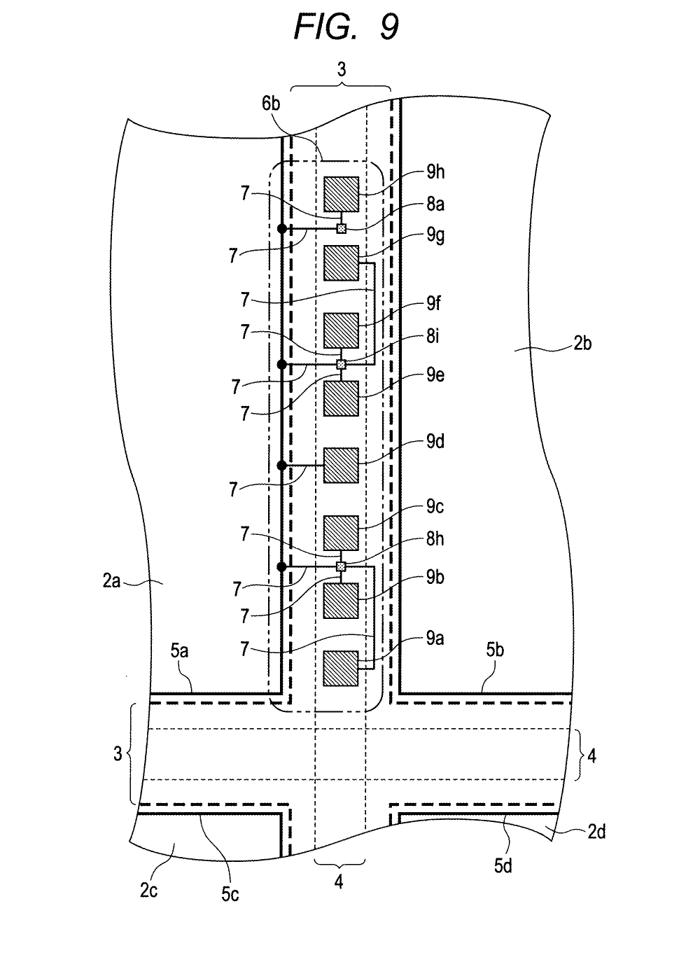

Next, a semiconductor device 10 according to the fourth embodiment will be described referring to FIGS. 9 to 11B. The fourth embodiment is the same as the first embodiment except that the TEG elements 8 include a transistor. A detailed explanation is given below.

FIG. 9 is a plan view showing the structure of the semiconductor device 10 according to the fourth embodiment. In the fourth embodiment, a TEG element 8h and a TEG element 8i may be, for example, a transistor such as a FET (Field Effect Transistor), as described later. In the TEG element 8h, the well terminal is coupled to the seal ring 5a through a TEG wiring 7. In the TEG element 8h, a gate terminal, source terminal and drain terminal are coupled to electrode pads 9a, 9b, and 9c respectively. Similarly, in the TEG element 8i, the well terminal, gate terminal, source terminal, and drain terminal are coupled to the seal ring 5a and electrode pads 9g, 9e, 9f respectively.

Also the electrode pad 9d is directly coupled to the seal ring 5a. In addition, the TEG element 8a as a resistance is coupled to the seal ring 5a and electrode pad 9h.

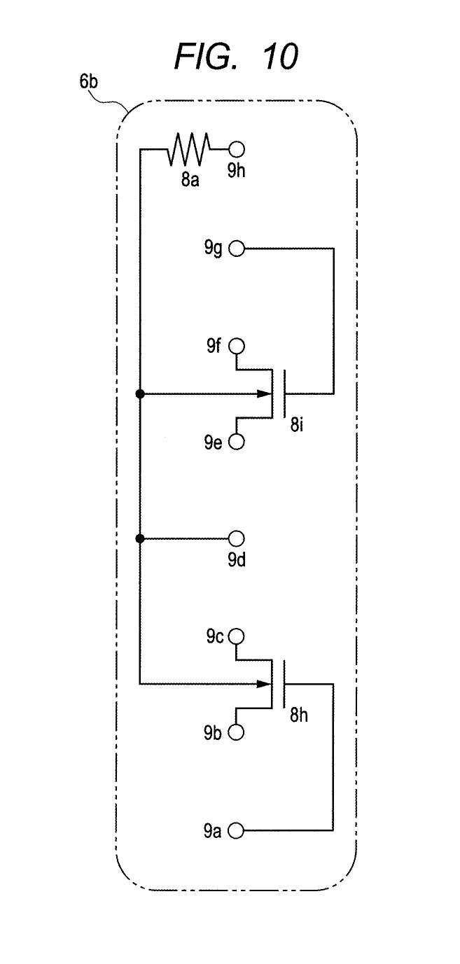

FIG. 10 is an equivalent circuit diagram for the TEG pattern 6b according to the fourth embodiment. As shown in FIG. 10, the electrode pad 9d is coupled to the well terminals of the TEG elements 8h and 8i through the seal ring 5a. Therefore, in the testing process, the well potential of the TEG elements 8h and 8i can be controlled by controlling the common electrode pad 9d.

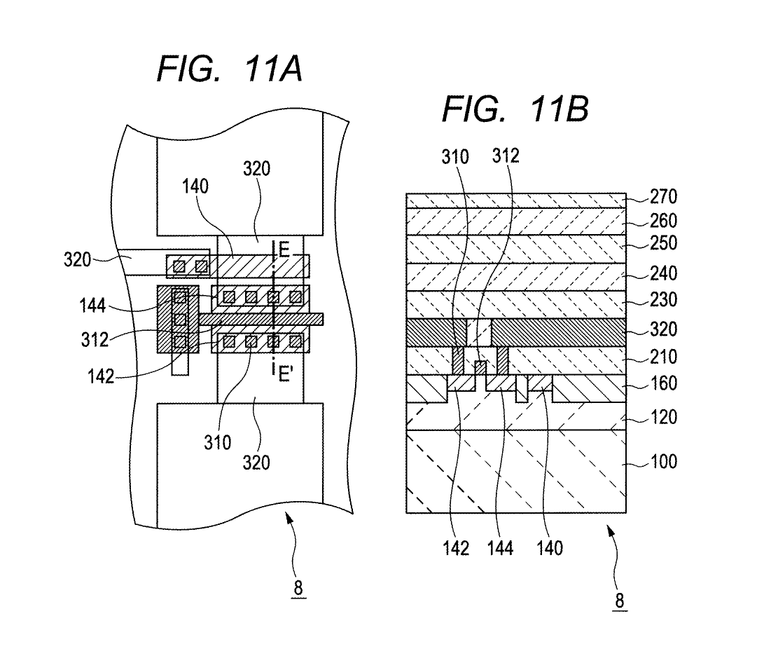

FIGS. 11A and 11B show a TEG element 8 according to the fourth embodiment in enlarged form. FIG. 11A is a plan view of the TEG element 8 according to the fourth embodiment and FIG. 11B is a sectional view taken along the line E-E′ of FIG. 11A. The TEG element 8 shown in FIGS. 11A and 11B is the TEG element 8h or 8i shown in FIGS. 9 and 10. The TEG element 8a is the same as in the first embodiment.

As shown in FIG. 11A, a source region 142 and a drain region 144 are formed on both sides of a gate terminal 312. A diffusion layer 140 is formed in a region not overlapping the source region 142 and drain region 144 in a plan view and functions as a well terminal.

As shown in FIG. 11B, the source region 142 and drain region 144 are formed in an opening of the element isolation region 160. The diffusion layer 140 as the well terminal is formed in another opening of the element isolation region 160 spaced from the source region 142 and drain region 144. The gate terminal 312 is formed over the channel region (not shown) between the source region 142 and drain region 144. Also a first via 310 is formed over each of the source region 142 and drain region 144.

According to the fourth embodiment, the TEG elements 8 include the abovementioned transistors. This means that the transistor characteristics in the semiconductor chip 2 can be predicted by testing the TEG pattern 6b.

As a comparative example, if a common wiring is not used, in order to measure the two transistors, TEG elements 8h and 8i, a total of eight electrode pads will be needed for the well, gate, source and drain of each transistor.

On the other hand, according to the fourth embodiment, the well terminals of the TEG elements 8h and 8i are coupled to the seal ring 5a. This means that the seal ring 5a may be used as a common wiring for the well terminals. Therefore, the number of electrode pads needed to measure the TEG elements 8h and 8i is seven. In other words, the number of electrode pads can be decreased. Furthermore, by coupling the extra electrode pad 9h to the TEG element 8a as a resistance, the number of TEG elements can be increased while the number of electrode pads is unchanged.

### Fifth Embodiment

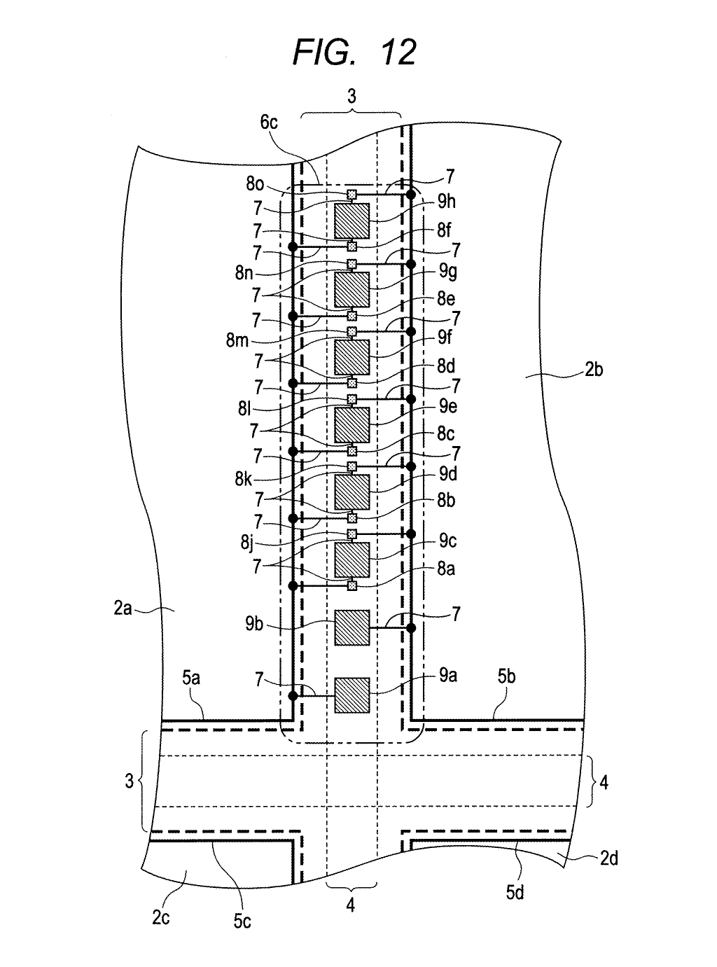

Next, a semiconductor device 10 according to the fifth embodiment will be described referring to FIGS. 12 to 14B. The fifth embodiment is the same as the first embodiment except that two seal rings 5a and 5b are used as common wirings and the TEG elements 8 include short-circuit check elements. A detailed explanation is given below.

FIG. 12 is a plan view showing the structure of the semiconductor device 10 according to the fifth embodiment. As shown in FIG. 12, the electrode pad 9a is directly coupled to seal ring 5a. On the other hand, the electrode pad 9b is coupled to the seal ring 5b which is opposite to the seal ring 5a with the dicing region 3 between them. This means that the fifth embodiment uses the two seal rings 5a and 5b as common wirings.

TEG elements 8a to 8f as resistances are provided in the dicing region 3. The TEG elements 8a to 8f as resistances are directly coupled to the seal ring 5a. In addition, TEG elements 8j to 8o as short-circuit check elements are provided in the dicing region 3 as described later. The TEG elements 8j to 8o as short-circuit check elements are directly coupled to the seal ring 5b.

Electrode pads 9c to 9h are provided between the TEG elements 8a to 8f as resistances and the TEG elements 8j to 8o as short-circuit check elements through TEG wirings 7 respectively.

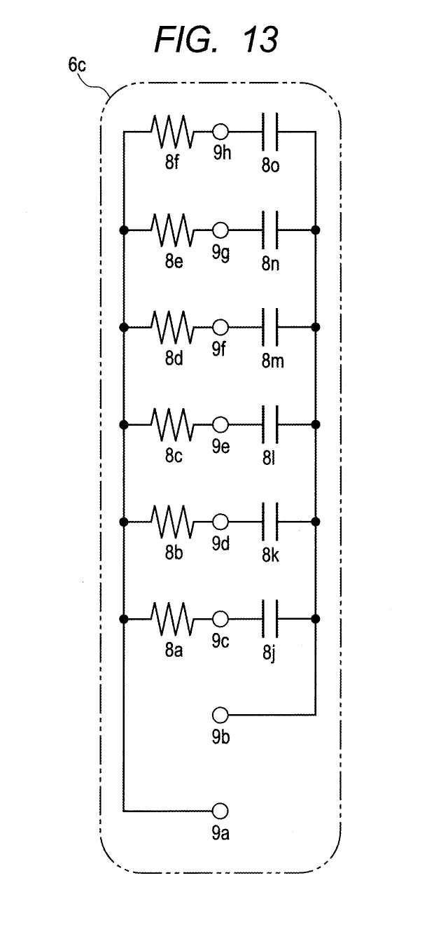

FIG. 13 is an equivalent circuit diagram for the TEG pattern 6c according to the fifth embodiment. The TEG elements 8j to 8o as short-circuit check elements are shown as capacitors. The seal rings 5a and 5b are common wirings on both sides in FIG. 13 as described above. The testing process for the TEG pattern 6c will be described in detail later.

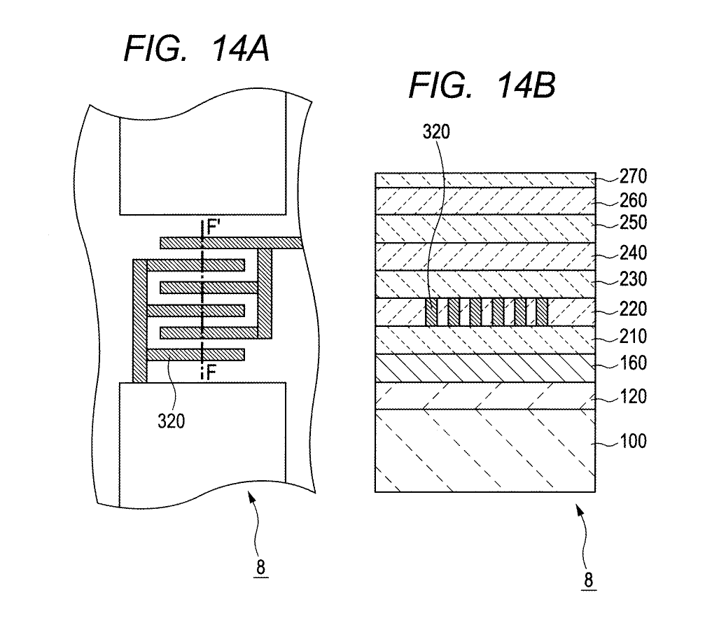

FIGS. 14A and 14B show a TEG element 8 according to the fifth embodiment in enlarged form. FIG. 14A is a plan view of the TEG element 8 according to the fifth embodiment and FIG. 14B is a sectional view taken along the line F-F′ of FIG. 14A. The TEG element 8 in FIG. 14 is the same as the TEG elements 8j to 8c in FIGS. 12 and 13. The TEG elements 8a to 8f are the same as in the first embodiment.

The TEG element 8 in FIG. 14A is a short-circuit check element in which wirings (first wirings 320) are alternately arranged in a comb-like pattern.

As shown in FIG. 14B, the first wirings 320 of the TEG element 8 are located in a first wiring formation insulating layer 220. In the TEG element 8, the first wirings 320, arranged alternately, are spaced from each other at regular intervals which are equal to the regular spacing intervals for the first wirings 320 of the semiconductor chip 2a and so on. This means that in the testing process, whether there is a short-circuit due to defective patterning in the first wirings 320 of the semiconductor chip 2a and so on can be estimated by checking the leakage current of the TEG element 8.

Next, the testing process for the TEG pattern 6c will be described referring to FIG. 13. How the TEG elements 8a and 8j coupled to the electrode pad 9c are tested in the testing process for the TEG pattern 6c is explained below as an example.

The electrode pads 9a and 9b are fixed to the GND potential. As described above, the electrode pads 9a and 9b are coupled to the seal rings 5a and 5b respectively. Therefore, the seal rings 5a and 5b are also fixed to the GND potential.

Then, voltage is applied to the electrode pad 9c coupled to the TEG elements 8a and 8j. At this time, the electric currents flowing from the electrode pads 9a and 9b are measured. This means that the resistance can be measured with the TEG element 8a. If a current flows from the electrode pad 9b, it is considered that there is a short circuit in the TEG element 8j. In other words, it is considered that in the semiconductor chip 2a and so on, there is a short circuit in an area in which wirings are arranged at the same intervals as in the TEG elements 8.

According to the fifth embodiment, the TEG elements 8 include short-circuit check elements as mentioned above. This means that whether there is a short circuit in the semiconductor chip 2 can be estimated by testing with the TEG pattern 6c.

According to the fifth embodiment, the seal rings 5a and 5b are used as common wirings. Consequently a larger number of TEG elements 8 can be provided in the dicing region 3.

### Sixth Embodiment

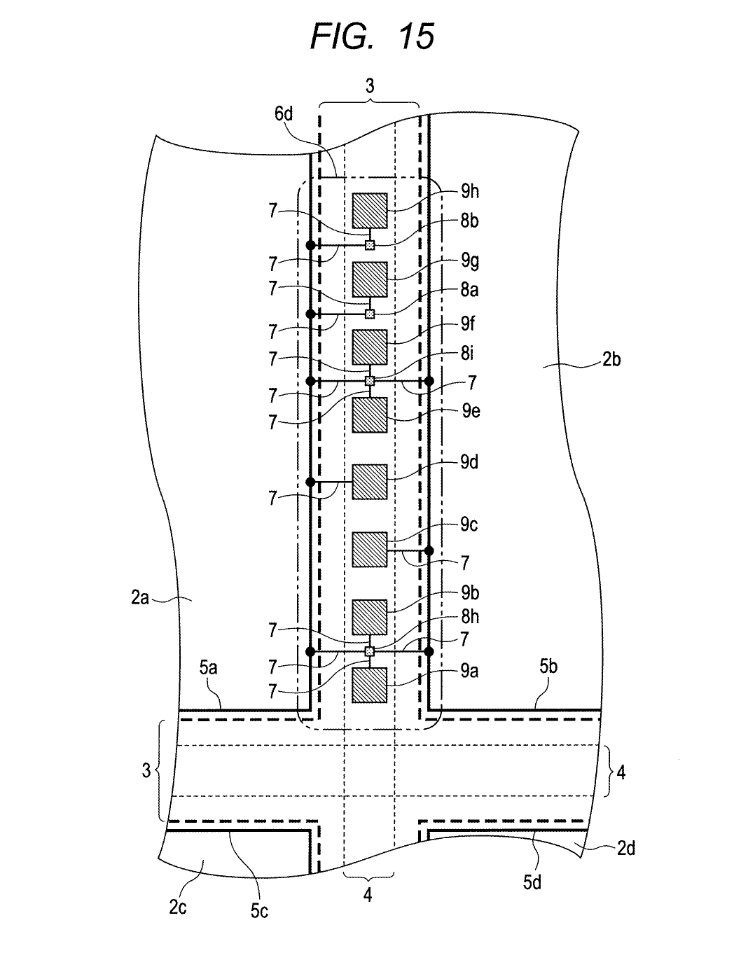

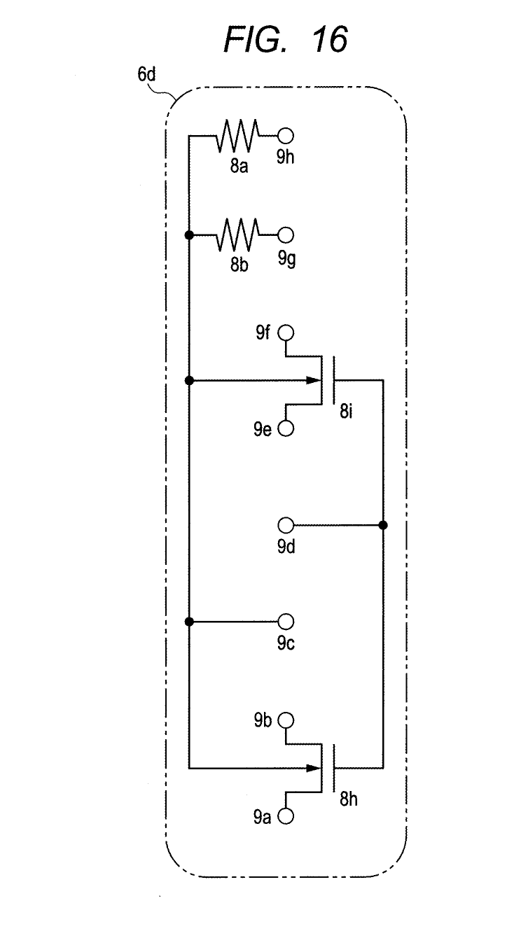

Next, a semiconductor device 10 according to the sixth embodiment will be described referring to FIGS. 15 and 16. The sixth embodiment is the same as the fourth embodiment except that two seal rings 5a and 5b are used as common wirings. A detailed explanation is given below.

FIG. 15 is a plan view showing the structure of the semiconductor device 10 according to the sixth embodiment. In the fourth embodiment, TEG elements 8h and 8i are, for example, FETs as described later. The well terminals of the TEG elements 8h and 8i are coupled to the seal ring 5a through TEG wirings 7. On the other hand, the gate terminals of the TEG elements 8h and 8i are coupled to the seal ring 5b through TEG wirings 7. This means that in the sixth embodiment, while the seal ring 5a serves as a common wiring for the well terminals, the seal ring 5b serves as a common wiring for the gate terminals.

The source terminal and drain terminal of the TEG element 8h are coupled to the electrode pads 9a and 9b respectively. Similarly, the source terminal and drain terminal of the TEG element 8i are coupled to the electrode pads 9e and 9f respectively.

The electrode pads 9c and 9d are directly coupled to the seal rings 5a and 5b respectively. The TEG element 8a as a resistance is coupled to the seal ring 5a and electrode pad 9h. Similarly, the TEG element 8b as a resistance is coupled to the seal ring 5a and electrode pad 9g.

FIG. 16 is an equivalent circuit diagram for the TEG pattern 6b according to the sixth embodiment. As shown in FIG. 16, the electrode pad 9c is coupled to the well terminals of the TEG elements 8h and 8i through the seal ring 5a. Therefore, in the testing process, the well potentials of the TEG elements 8h and 8i can be controlled by controlling the common electrode pad 9c.

On the other hand, the electrode pad 9d is coupled to the gate terminals of the TEG elements 8h and 8i through the seal ring 5b. Therefore, in the testing process, the gate potentials of the TEG elements 8h and 8i can be controlled by controlling the common electrode pad 9d.

According to the sixth embodiment, the same advantageous effects as those of the fourth embodiment can be achieved.

Specifically, according to the sixth embodiment, the well terminals of the TEG elements 8h and 8i are coupled to the seal ring 5a and the gate terminals thereof are coupled to the seal ring 5b. This means that the seal ring 5a can be used as a common wiring for the well terminals and the seal ring 5b can be used as a common wiring for the gate terminals. Therefore, the number of electrode pads needed to measure the TEG elements 8h and 8i is six. In other words, the number of electrode pads can be decreased. Furthermore, by coupling the extra electrode pads 9g and 9h to the TEG elements 8a and 8b as resistances, the number of TEG elements can be increased while the number of electrode pads is unchanged.

### Seventh Embodiment

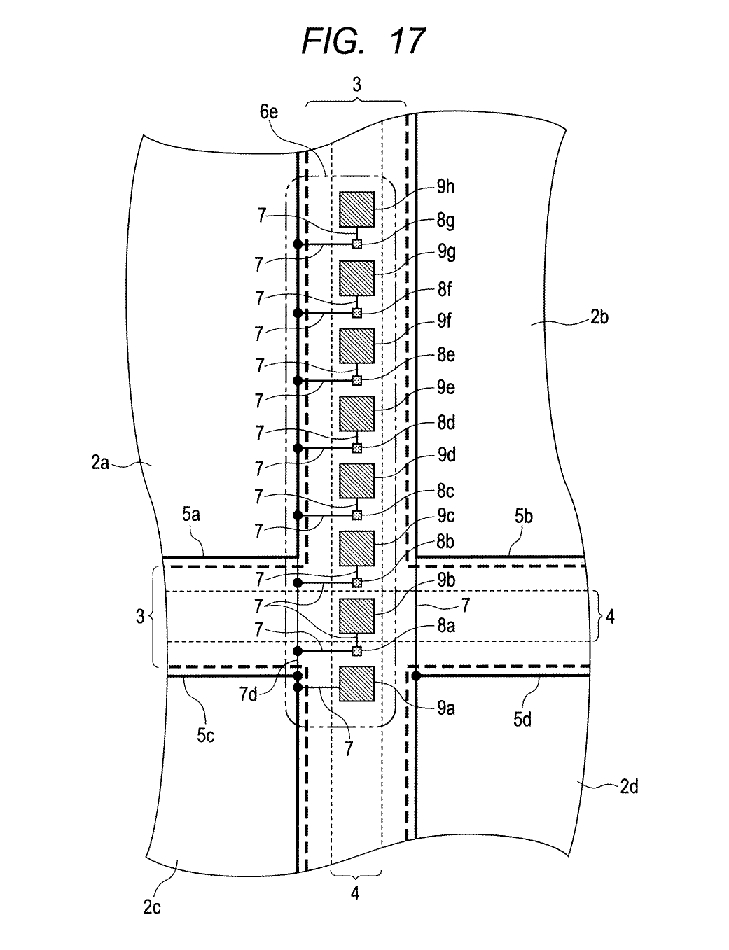

Next, a semiconductor device 10 according to the seventh embodiment will be described referring to FIG. 17. The seventh embodiment is the same as the first embodiment except the following point. The semiconductor substrate 100 is not divided into individual chips. At least one TEG wiring (7d) is coupled to the seal rings 5 (seal rings 5a and 5c) of neighboring semiconductor chips 2 (semiconductor chips 2a and 2c). A detailed explanation is given below.

FIG. 17 is a plan view showing the structure of the semiconductor device according to the seventh embodiment. The semiconductor substrate 100 is not divided into individual chips. The figure shows that the semiconductor chips 2a, 2b, 2c, and 2d are adjacent to each other and not separated from each other as individual chips.

The TEG wiring 7d is coupled to the seal rings 5a and 5b of the neighboring semiconductor chips 2a and 2c. The “TEG wiring 7d” here is formed, for example, in the same layer in which the TEG wiring 7a for electrode coupling as mentioned above is formed. In other words, the TEG wiring 7d is located directly on the top layer of the interlayer insulating layer 200.

This means that in the seventh embodiment, the TEG pattern 6e extends across neighboring semiconductor chips 2.

Next the advantageous effects of the seventh embodiment will be described.

If many TEG elements 8 are to be disposed, in some cases all the elements cannot be disposed by coupling them only to the seal ring 5a of the semiconductor chip 2a as in the first embodiment.

On the other hand, according to the seventh embodiment, the TEG wiring 7d is coupled to the seal rings 5 of neighboring semiconductor chips 2. This means that coupling to the seal rings 5 of plural semiconductor chips 2 enables the TEG pattern 6e to cover a broader area.

Although the TEG wiring 7d is coupled to two seal rings 5 in the seventh embodiment, other TEG wirings 7 may be used for coupling to three or more seal rings 5.

### Eighth Embodiment

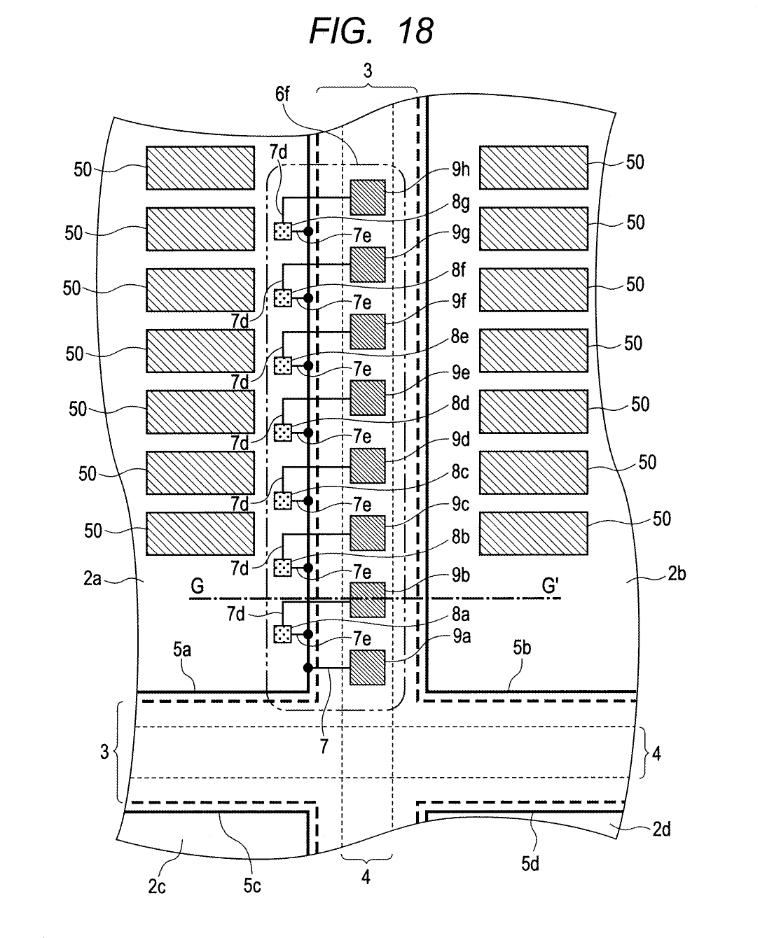

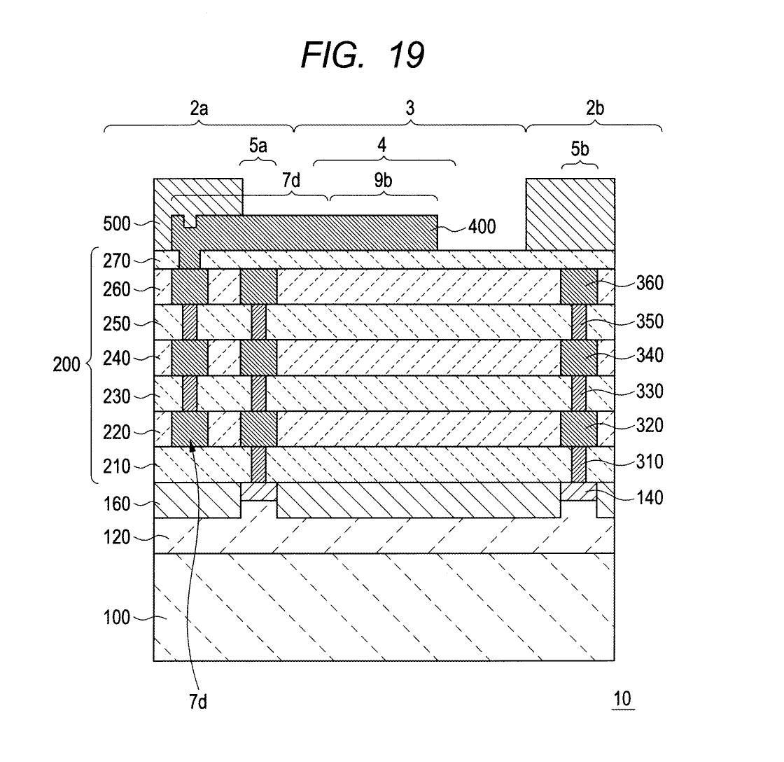

Next, a semiconductor device 10 according to the eighth embodiment will be described referring to FIGS. 18 and 19. The eighth embodiment is the same as the first embodiment except the following point. TEG elements 8a to 8g are located on the inside of the seal ring 5a in a plan view. TEG wirings 7d each have one end coupled to one of the TEG elements 8a to 8g and the other end extending toward the end face of the periphery of the semiconductor chip 2a without contact with the seal ring 5a and beyond the seal ring 5a. TEG wirings 7e for element coupling each have one end coupled to one of the TEG elements 8a to 8g and the other end coupled to the seal ring 5a. A detailed explanation is given below.

FIG. 18 is a plan view showing the structure of the semiconductor device 10 according to the eighth embodiment. As shown in FIG. 18, the TEG elements 8a to 8g are located on the inside of the seal ring 5a in a plan view. The “inside of the seal ring 5a” here means that the elements lie on the inner side of the seal ring 5a which is inside the semiconductor chip 2a in a plan view.

On the inside of the seal ring 5a, electrode pads 50 coupled to the internal circuit (not shown) of the semiconductor chip 2a are provided. The distance between each electrode pad 50 and the seal ring 5a in the semiconductor chip 2a is, for example, 10 micrometers or so. This prevents cracking in the passivation film 500 or deformation of the aluminum of the electrode pad 50 due to thermal stress in the process for manufacturing the semiconductor device 10.

The TEG elements 8a to 8g are located between the seal ring 5a and the electrode pads 50 coupled to the internal circuit (not shown) of the semiconductor chip 2a. Therefore, the dead space inside the semiconductor chip 2a can be effectively used as the space for the TEG elements 8a to 8g.

As for the TEG wirings 7d, one end is coupled to one of the TEG elements 8a to 8g and the other end extends toward the end face of the periphery of the semiconductor chip 2a without contact with the seal ring 5a and beyond the seal ring 5a. In this case, the other ends of the TEG wirings 7d are coupled to electrode pads 9b to 9h.

In the eighth embodiment, a TEG wiring 7 may have one end coupled to the seal ring 5a and the other end extending toward the end face of the periphery of the semiconductor chip 2a and coupled to the electrode pad 9a.

As for the TEG wirings 7e for element coupling, one end is coupled to one of the TEG elements 8a to 8g and the other end is coupled to the seal ring 5a. In other words, the TEG wirings 7e for element coupling are located on the inside of the seal ring 5a in a plan view, like the TEG elements 8a to 8g. Therefore, the TEG elements 8a to 8g and TEG wirings 7e for element coupling are left inside the semiconductor chip 2a after dicing.

FIG. 19 is a sectional view showing the structure of the semiconductor device according to the eighth embodiment. FIG. 19 is a sectional view taken along the line G-G′ of FIG. 18.

As shown in FIG. 19, a fourth wiring 400 including the electrode pad 9b is located directly on the top layer of the interlayer insulating layer 200. A TEG wiring 7d is coupled to the TEG element 8a through a portion of the fourth wiring 400, the third wiring 360, third via 350, second wiring 340, second via 330, and a via (indicated by arrow 7d in FIG. 19) in the same layer in which the first wiring 320 is located.

The above expression “without contact with the seal ring 5a” in connection with the other end of the TEG wiring 7d implies that the TEG wiring 7d and the seal ring are spaced from each other. Specifically, the TEG wiring 7d is isolated from the seal ring 5a by the fourth interlayer insulating layer 270.

Also, the above expression “beyond the seal ring 5a” in connection with the other end of the TEG wiring 7d implies that the TEG wiring 7d is located above the fourth interlayer insulating layer 270 lying over the seal ring 5a.

As mentioned earlier, the fourth interlayer insulating layer 270 is made of, for example, SiN. For this reason, moisture does not spread into the fourth interlayer insulating layer 270 even when the TEG wirings 7 are arranged as mentioned above.

According to the eighth embodiment, the TEG elements 8 are located on the inside of the seal ring 5 in a plan view. Therefore, the number of TEG wirings 7, etc. inside the dicing region 3 can be decreased. This means that the amount of metal swarf in dicing can be reduced.

### Ninth Embodiment

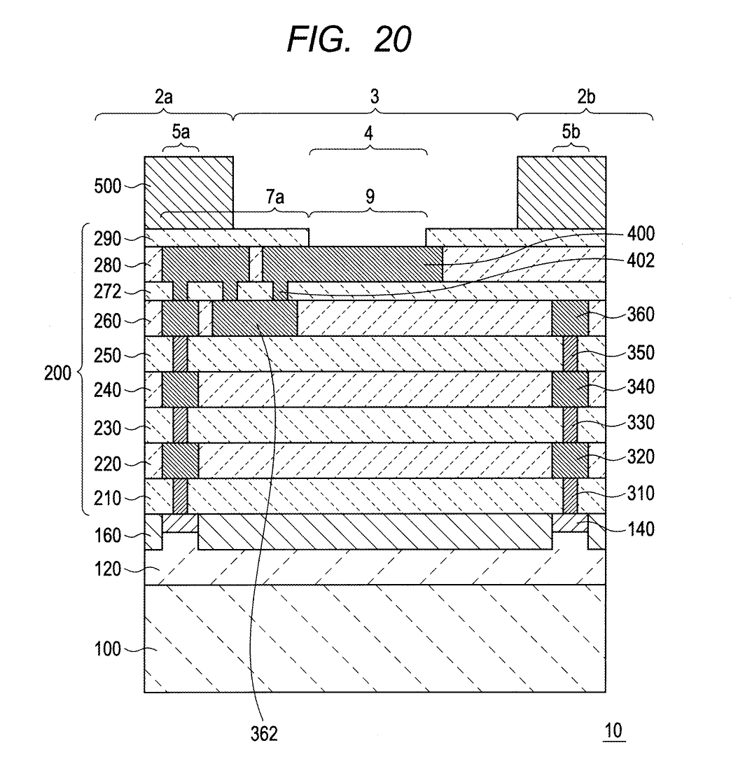

Next, a semiconductor device 10 according to the ninth embodiment will be described referring to FIG. 20. The ninth embodiment is the same as the first embodiment except the following point. An electrode pad 9 and a TEG wiring 7a for electrode coupling contain Cu. The TEG wiring 7a for electrode coupling lies below the top layer of the interlayer insulating layer 200 and includes a wiring (third wiring 362) lying nearer to the semiconductor chip 2 than to the portion (cutting region 4) of the dicing region 3 to be cut with the dicing blade. A detailed explanation is given below.

FIG. 20 is a sectional view showing the structure of the semiconductor device according to the ninth embodiment. In the ninth embodiment, for example, Cu is used for the electrode pad 9 and the TEG wiring 7a for electrode coupling. The “TEG wiring 7a for electrode coupling” here is coupled to the seal ring 5a through a fourth via 402 in the interlayer insulating layer 200 and through a plurality of layers (the third wiring 362 and a portion of the fourth wiring 400) as described later. Therefore, the cross-sectional structure is different from that of the first embodiment as described below.

As shown in FIG. 20, the layers up to the third via formation insulating layer 250 are the same as in the first embodiment. A third wiring formation insulating layer 260, a fourth via formation insulating layer 272, a fourth wiring formation insulating layer 280, and a fifth interlayer insulating layer 290 are formed over the third via formation insulating layer 250. The fourth via formation insulating layer 272 and fourth wiring formation insulating layer 280 are, for example, low-k layers. The fifth interlayer insulating layer 290 has a function as a protective film and is, for example, SiN film.

A fourth wiring 400 including the electrode pad 9 is formed in the fourth wiring formation insulating layer 280. Furthermore, the fourth wiring 400 includes a portion of the TEG wiring 7a for electrode coupling.

For example, the TEG wiring 7a for electrode coupling includes fourth vias 402. The portion of the TEG wiring 7a for electrode coupling in the fourth wiring 400 is coupled through the fourth vias 402 to the third wiring 362 which will be described later. The fourth vias 402 may be included in the fourth wiring 400.

The TEG wiring 7a for electrode coupling has a wiring portion below the top layer of the interlayer insulating layer 200. In the ninth embodiment, that wiring portion is the third wiring 362. The third wiring 362 lies nearer to the semiconductor chip 2 than to the portion (cutting region 4) of the dicing region 3 to be cut with the dicing blade. This eliminates the possibility that the wiring is cut during dicing and its end face is exposed. Therefore, the wiring portion of the TEG wiring 7a for electrode coupling does not get oxidized. The wiring portion need not lie in the same layer as the third wiring 360 and instead it may lie in another lower wiring formation insulating layer.

The third wiring 362, which is the wiring portion as mentioned above, may extend to the seal ring 5a.

In the ninth embodiment, the TEG wiring 7a for electrode coupling is coupled to the seal ring 5a in the same layer as the electrode pad 9. Specifically, the TEG wiring 7a for electrode coupling is coupled to the seal ring 5a in the fourth wiring 400 by being coupled again through the fourth vias 402 to the fourth wiring 400 lying in the same layer as the electrode pad 9. This retards the spread of moisture even if the third wiring 362 should be exposed due to chipping during dicing.

Next, the advantageous effects of the ninth embodiment will be described.

If a wiring containing Cu is exposed as a result of dicing, the Cu-containing wiring may get oxidized due to moisture absorption. If such oxidation spreads to the seal ring 5 or semiconductor chip 2, a defect such as cracking may occur.

On the other hand, according to the ninth embodiment, the Cu-containing TEG wiring 7a for electrode coupling is located below the top layer of the interlayer insulating layer 200 and has a wiring portion nearer to the semiconductor chip 2 than to the cutting region 4 of the dicing region 3. This prevents the Cu-containing wiring from being exposed as a result of dicing. Therefore, according to the ninth embodiment, the wiring portion of the TEG wiring 7a for electrode coupling does not get oxidized and cracking or a similar problem can be suppressed.

### Tenth Embodiment

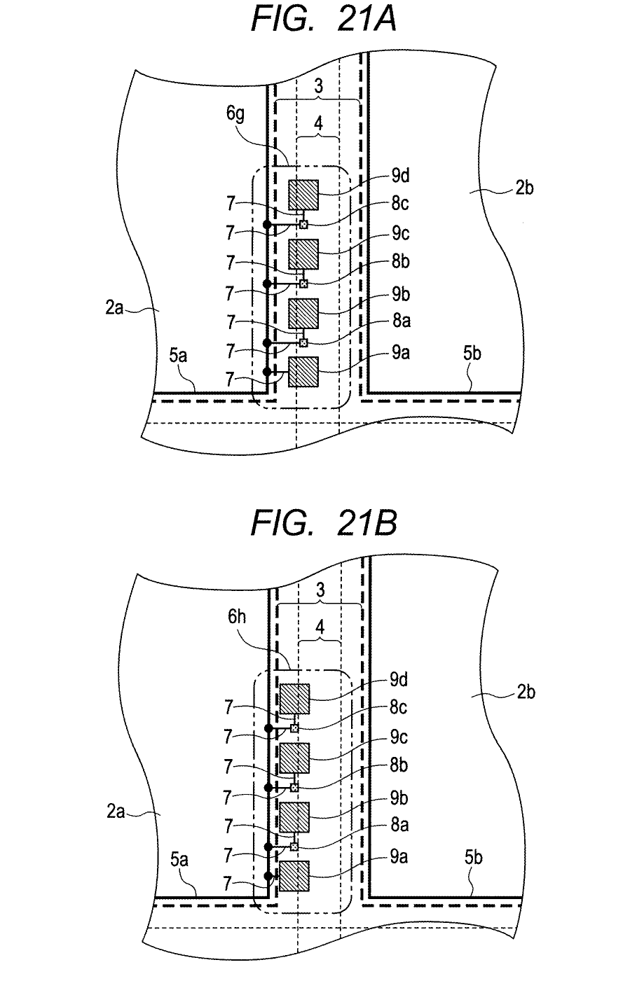

Next, a semiconductor device 10 according to the tenth embodiment will be described referring to FIGS. 21A and 21B. The tenth embodiment is the same as the first embodiment except that the electrode pad 9a and so on or the TEG element 8a and so on are located near to the semiconductor chip 2a across the edge of the cutting region 4. A detailed explanation is given below.

FIGS. 21A and 21B are plan views showing the structure of the semiconductor device 10 according to the tenth embodiment, in which FIGS. 21A and 21B show different arrangements of the electrode pad 9a and so on or TEG element 8a and so on. FIGS. 21A and 21B show the wafer which is not diced yet.

In the case shown in FIG. 21A, the electrode pads 9a to 9d are located near to the semiconductor chip 2a across the edge of the cutting region 4. As a result of dicing the semiconductor substrate 100, the semiconductor device 10 is obtained as the semiconductor chip 2a including the TEG wirings 7 coupled to the seal ring 5a and some portions of the electrode pads 9a to 9d which remain intact.

In the case shown in FIG. 21B, both the electrode pads 9a to 9d and the TEG elements 8a to 8c are located near to the semiconductor chip 2a across the edge of the cut region 4. As a result of dicing the semiconductor substrate 100, the semiconductor device 10 is obtained as the semiconductor chip 2a including the TEG wirings 7 coupled to the seal ring 5a, some portions of the electrode pads 9a to 9d, and some portions of the TEG elements 8a to 8c which remain intact.

According to the tenth embodiment, the electrode pad 9a and so on or the TEG element 8a and so on are located near to the semiconductor chip 2a across the edge of the cutting region 4. Consequently, in a plan view, the electrode pad 9a and so on or TEG element 8a and so on are partially left in the semiconductor device 10 inside the cutting region 4. Even if that is the case, the amount of metal swarf in dicing is decreased and chipping or cracking is reduced.

In the embodiments described above, the TEG element 8a and so on may include different elements according to the first to ninth embodiments. Alternatively, the TEG element 8a and so on may be inductors, capacitors or the like.

The preferred embodiments of the present invention have been so far described referring to the drawings but they are just illustrative and the invention may be embodied in other various ways.

1. A semiconductor device comprising:
a semiconductor substrate which is to be or has been divided into individual semiconductor chips by dicing;
an interlayer insulating layer formed over the semiconductor substrate;
a seal ring provided in the interlayer insulating layer and formed along a periphery of the semiconductor chip; and
a TEG wiring having one end coupled to the seal ring and the other end extending toward an end face of the periphery of the semiconductor chip.

2. The semiconductor device according to claim 1, further comprising:
a TEG element provided in the semiconductor substrate or the interlayer insulating layer and coupled to the seal ring through the TEG wiring for element coupling.

3. A semiconductor device comprising:
a semiconductor substrate which is to be or has been divided into individual semiconductor chips by dicing;
an interlayer insulating layer formed over the semiconductor substrate;
a seal ring provided in the interlayer insulating layer and formed along a periphery of the semiconductor chip;
a TEG element provided on the inside of the seal ring in a plan view;
a TEG wiring having one end coupled to the TEG element and the other end extending toward an end face of the periphery of the semiconductor chip without contact with the seal ring and beyond the seal ring; and
a TEG wiring for element coupling having one end coupled to the TEG element and the other end coupled to the seal ring.

4. The semiconductor device according to claim 2, wherein the TEG element includes a resistance.

5. The semiconductor device according to claim 4, wherein the resistance is a wiring resistance.

6. The semiconductor device according to claim 4, wherein the resistance is a diffusion resistance layer formed by doping impurities in the semiconductor substrate.

7. The semiconductor device according to claim 2, wherein the TEG element includes a short-circuit check element with wirings alternately arranged in a comb-like pattern.

8. The semiconductor device according to claim 2, wherein the TEG element includes a transistor.

9. The semiconductor device according to claim 2, wherein the TEG element includes a plurality of vias provided in the interlayer insulating layer.

10. The semiconductor device according to claim 1, further comprising:
an electrode pad located in a dicing region outside the seal ring in a plan view and directly on a top layer of the interlayer insulating layer and coupled to the TEG wiring for electrode coupling.

11. The semiconductor device according to claim 10, wherein the electrode pad and the TEG wiring for electrode coupling are made of Al and located directly on the top layer of the interlayer insulating layer.

12. The semiconductor device according to claim 10,
wherein the electrode pad and the TEG wiring for electrode coupling contain Cu;
wherein the TEG wiring for electrode coupling lies below the top layer of the interlayer insulating layer and includes a wiring portion lying nearer to the semiconductor chip than to a region of the dicing region to be cut with a dicing blade.

13. The semiconductor device according to claim 12, wherein the TEG wiring for electrode coupling is coupled to the seal ring in a layer in which the electrode pad lies.

14. The semiconductor device according to claim 10, wherein a width of the electrode pad is smaller than a width of a dicing blade with which the semiconductor substrate is diced.

15. The semiconductor device according to claim 1,
wherein the semiconductor substrate is not divided into individual chips yet;
wherein at least one of the TEG wirings is coupled to the seal ring of one of a plurality of neighboring semiconductor chips.

16. The semiconductor device according to claim 1, wherein the semiconductor substrate includes a diffusion layer which is provided in a portion in contact with the seal ring and doped with impurities having conductivity opposite to conductivity of the semiconductor substrate.

17. The semiconductor device according to claim 1, wherein the seal ring is a grounding wiring.

18. The semiconductor device according to claim 1, wherein the interlayer insulating layer includes a low-k layer with a dielectric constant of 3 or less.

19. A method for manufacturing a semiconductor device comprising the steps of:
forming a multilayer interconnection structure including an interlayer insulating layer over a semiconductor substrate which is divided into a plurality of semiconductor chips;
at the step of forming the multilayer interconnection structure, forming a seal ring in the interlayer insulating layer along a periphery of the semiconductor chip; and
forming a TEG wiring having one end coupled to the seal ring and the other end extending toward an end face of the periphery of the semiconductor chip.

20. The method for manufacturing a semiconductor device according to claim 19, wherein at the step of forming the multilayer interconnection structure, in a dicing region outside the seal ring in a plan view, an electrode pad which is coupled to the TEG wiring for electrode coupling is formed directly on a top layer of the interlayer insulating layer.

21. The method for manufacturing a semiconductor device according to claim 19, wherein at the step of forming the multilayer interconnection structure, a TEG elements which is coupled to the seal ring through the TEG wiring for element coupling is formed in the semiconductor substrate or the interlayer insulating layer.

22. The method for manufacturing a semiconductor device according to claim 21, further comprising the step of:
testing the TEG element by applying voltage to the electrode pad,
wherein if a defect is found in the TEG element at the testing step, it is considered that a semiconductor element in the semiconductor chip has the defect and if no defect is found in the TEG element, it is considered that the semiconductor element in the semiconductor chip has no defect and is allowed to be shipped.

23. The method for manufacturing a semiconductor device according to claim 22, further comprising:
after the testing step, a dicing step in which dicing is done in the dicing region of the semiconductor substrate including the electrode pad to divide the substrate into the semiconductor chips.
